(19) United States
(12) Patent Application Publication
(10) Pub. No.: US 2024/0087647 A1
(43) Pub. Date: Mar. 14, 2024

(54) NONVOLATIVE MEMORY DEVICES WITH CHARGE TRAP TRANSISTOR STRUCTURES AND METHODS OF OPERATION THEREOF

(71) Applicant: THE REGENTS OF THE UNIVERSITY OF CALIFORNIA, Oakland, CA (US)

(72) Inventors: Sepideh NOURI, Los Angeles, CA (US); Subramanian IYER, Los Angeles, CA (US)

(73) Assignee: THE REGENTS OF THE UNIVERSITY OF CALIFORNIA, Oakland, CA (US)

(21) Appl. No.: 18/263,522

(22) PCT Filed: Jan. 28, 2022
(86) PCT No.: PCT/US2022/014440

§ 371 Date: Jul. 28, 2023

Related U.S. Application Data
(60) Provisional application No. 63/143,319, filed on Jan. 29, 2021.

(51) Int. Cl. G11C 16/04; G11C 16/08; G11C 16/10; G11C 16/26

(52) U.S. Cl. CPC G11C 16/0475; G11C 16/08; G11C 16/10; G11C 16/26

(57) ABSTRACT

Present implementations are directed to nonvolatile memory devices with charge trap transistor structures. Example implementations can include a method of memory storage, by programming a first data node operatively coupled to a first charge trap transistor to a first level above a threshold, decreasing, below the threshold, a first voltage at the first charge trap transistor, increasing, above the threshold, the first voltage at the first charge trap transistor, and reprogramming, the first data node to the first level, in response to an interruption of the first voltage at the first charge trap transistor caused by the decreasing and the increasing.

### CROSS-REFERENCE TO RELATED PATENT APPLICATIONS

This application claims priority to U.S. Provisional Patent Application Ser. No. 63/143,319, entitled “CHARGE TRAP TRANSISTOR-BASED NONVOLTATILE STATIC RAM DEVICE AND METHOD THEREFOR,” filed Jan. 29, 2021, the contents of all such applications being hereby incorporated by reference in its entirety and for all purposes as if completely and fully set forth herein.

### TECHNICAL FIELD

The present implementations relate generally to electronic memory devices, and more particularly to nonvolatile memory devices with charge trap transistor structures.

### BACKGROUND

Conventional memory cells may lose their data state when losing power, including losing voltage to a memory cell below a particular threshold voltage.

### SUMMARY

Present implementations are directed to an embeddable nonvolatile memory device using charge trap transistors. Methods of manufacturing present implementations can further advantageously be accomplished with high efficiency, eliminating the need for extra masks or fabrication steps, such as a floating gate. The resulting device can rapidly store data on-chip and then transition into a low-power mod, such as a sleep mode. By storing data advantageously on-chip, present implementations are advantageously applicable to many times of system with a low or limited power budget, resulting in at least longer device life, reduction in size and weight or consumer or commercial products, and improved redundancy in the event of power loss. Systems with a low power budget can include IoT sensors, implantable medical devices, systems that rely on power harvesting and see fluctuations in their power supply, and systems using intermittent-computing. These systems may sleep when losing power, though maintaining data upon restart is critical. These systems can also sense and store data, then transition to idle mode for an extended period of time until the next scheduled action. As one example, an action can include a measurement of blood glucose level every hour.

As one example, in intermittent computing, a system transitioning to an idle mode can save a state of computation in nonvolatile memory and enter the idle, or sleep mode. When the system returns to a fully powered-on mode, or wakes, it can continue the computation from the saved state. Thus, a technological solution for nonvolatile memory devices with charge trap transistor structures is provided.

In some aspects, a method of memory storage can include programming a first data node operatively coupled to a first charge trap transistor to a first level above a threshold, decreasing, below the threshold, a first voltage at the first charge trap transistor, increasing, above the threshold, the first voltage at the first charge trap transistor, and reprogramming, the first data node to the first level, in response to an interruption of the first voltage at the first charge trap transistor caused by the decreasing and the increasing.

In some aspects, a method further can include programming the first charge trap transistor at the first level in a store mode.

In some aspects, the first level corresponds to a first digital state.

In some aspects, the programming the first data node includes setting the first node voltage at the first data node to the first level based on a first transistor voltage across a drain and a source of the first charge trap transistor.

In some aspects, a method can include programming a second data node operatively coupled to a second charge trap transistor to a second level.

In some aspects, a method further can include reprogramming, the second data node to the second level, in response to an interruption of the second voltage at the second charge trap transistor caused by the decreasing and the increasing.

In some aspects, a method further can include programming the second charge trap transistor at the second level in a store mode.

In some aspects, the second level corresponds to a second digital state.

In some aspects, the programming the second data node includes setting the second node voltage at the second data node to the second level based on a second voltage across a drain and a source of the second charge trap transistor.

In some aspects, a memory device, can include a first charge trap transistor, a second charge trap transistor, and a memory operatively coupled to the first charge trap transistor and the second charge trap transistor.

In some aspects, the first charge trap transistor and the second charge trap transistor are operatively coupled to an input voltage node.

In some aspects, the memory includes a nonvolatile static ram bitcell.

In some aspects, a device further can include a first input transistor operatively coupled with the first charge trap transistor, and a second input transistor operatively coupled with the second charge trap transistor.

In some aspects, the first input transistor is operatively coupled with a first input node.

In some aspects, the first input node includes a first bit line input node.

In some aspects, the second input transistor is operatively coupled with a second input node.

In some aspects, the second input node includes a second bit line input node.

In some aspects, the first input transistor is operatively coupled with a third input node.

In some aspects, the third input node includes a first word line input node.

In some aspects, a device further can include a first word line driver operatively coupled to the first word line input, the first word line driver can include at least one logical gate and operatively coupled with an address decoder.

In some aspects, the second input transistor is operatively coupled with a fourth input node.

In some aspects, the fourth input node includes a second word line input node.

In some aspects, a device further can include a second word line driver operatively coupled to the second word line input node, the second word line driver can include at least one logical gate and operatively coupled with an address decoder.

In some aspects, a device further can include a first selector device operatively coupled with the first charge trap transistor and a first output node, and a second selector device operatively coupled with the second charge trap transistor and a second output node.

In some aspects, a device further can include a read device operatively coupled with the first output node and the second output node, the read device can include a logical circuit.

In some aspects, the logical circuit includes an SR flip-flop.

In some aspects, a memory device can include a plurality of level shifter devices operatively responsive to a plurality of charge trap transistor devices, a write driver device operatively coupled with a plurality of bit line input nodes, a controller operatively coupled with a plurality of word line input nodes.

In some aspects, each of the charge trap transistor devices is operable to program, to a first level above a threshold, a plurality of data nodes operatively coupled to corresponding ones of the charge trap transistors, decrease, below the threshold, a plurality of voltages at the charge trap transistors, increase, above the threshold, the voltages at the charge trap transistors, and reprogram, in response to an interruption of the voltages at the charge trap transistors, the data nodes to the first level.

In some aspects, the interruption is caused by the decrease and the increase.

### BRIEF DESCRIPTION OF THE DRAWINGS

These and other aspects and features of the present implementations will become apparent to those ordinarily skilled in the art upon review of the following description of specific implementations in conjunction with the accompanying figures, wherein:

FIG. 1 illustrates a first electronic device in accordance with present implementations.

FIG. 2 illustrates a word line circuit in accordance with present implementations

FIG. 3 illustrates a read circuit in accordance with present implementations.

FIG. 4 illustrates a write circuit in accordance with present implementations. As

FIG. 5 illustrates a gate driver circuit in accordance with present implementations.

FIG. 6 illustrates an interface array in accordance with present implementations.

FIG. 7A illustrates a second electronic device in accordance with present implementations.

FIG. 7B illustrates a third electronic device in accordance with present implementations.

FIG. 8 illustrates a first voltage diagram in accordance with present implementations.

FIG. 9 illustrates a second voltage diagram in accordance with present implementations.

FIG. 10 illustrates a first method of operating a nonvolatile memory device with charge trap transistor structures, in accordance with present implementations.

FIG. 11 illustrates a second method of operating a nonvolatile memory device with charge trap transistor structures, further to the method of FIG. 10.

FIG. 12 illustrates a third method of operating a nonvolatile memory device with charge trap transistor structures, further to the method of FIG. 11.

FIG. 13 illustrates a fourth method of operating a nonvolatile memory device with charge trap transistor structures, in accordance with present implementations.

### DETAILED DESCRIPTION

The present implementations will now be described in detail with reference to the drawings, which are provided as illustrative examples of the implementations so as to enable those skilled in the art to practice the implementations and alternatives apparent to those skilled in the art. Notably, the figures and examples below are not meant to limit the scope of the present implementations to a single implementation, but other implementations are possible by way of interchange of some or all of the described or illustrated elements. Moreover, where certain elements of the present implementations can be partially or fully implemented using known components, only those portions of such known components that are necessary for an understanding of the present implementations will be described, and detailed descriptions of other portions of such known components will be omitted so as not to obscure the present implementations. Implementations described as being implemented in software should not be limited thereto, but can include implementations implemented in hardware, or combinations of software and hardware, and vice-versa, as will be apparent to those skilled in the art, unless otherwise specified herein. In the present specification, an implementation showing a singular component should not be considered limiting; rather, the present disclosure is intended to encompass other implementations including a plurality of the same component, and vice-versa, unless explicitly stated otherwise herein. Moreover, applicants do not intend for any term in the specification or claims to be ascribed an uncommon or special meaning unless explicitly set forth as such. Further, the present implementations encompass present and future known equivalents to the known components referred to herein by way of illustration.

In various memory devices and systems, a supply voltage must be at or above a minimum voltage to prevent data loss of the state of the memory device. Maintaining this minimum voltage can result in significant power leakage and wasted energy resources, because the memory device must continue to draw power while not performing useful computation. Various nonvolatile memory devices can store a state of a memory device without requiring maintaining a minimum voltage. However, such nonvolatile memory devices can require special manufacturing processes or materials incompatible with compact and versatile CMOS logic fabrication. Such manufacturing constraints can restrict implementation of nonvolatile memory in advanced devices or silicon. In addition, implementations including nonvolatile memory may require resource-intensive operating conditions, such as high voltage, or may not be compatible with embedding into a larger silicon system on chip or the like to cause signal propagation delays and reduce overall computations performance.

Present implementations are advantageously directed to nonvolatile memory devices with charge trap transistor (CTT) structures, to advantageously enable at least embedding ability in silicon, compatibility with CMOS, maximization of computational throughput, and simplified manufacturing. A CTT can include a MOSFET fabricated with a high-k gate dielectric. Present implementations can advantageously increase Vₜₕ of a CTT by applying a large+V_{GS} and +V_{DS}, to achieve self-heating assisted programming modes. As one example, a V_{GS} of 2.0V and a V_{DS} of 1.3V can result in a programming time of 1 ms and a ΔVₜₕ of 80 mV. Present implementations can decrease Vₜₕ of a CTT by applying a large negative V_{GS} in an erase mode. The device can demonstrate advantageously high durability and lifespan, where the CTT can be programmed and erased more than 10,000 times. Thus, when memory is idle, VDD can be turned off to eliminate the leakage power. Before VDD is turned off, the device can create a nonvolatile mismatch in the bitcells, to prepare them to enter into known states upon turning on. The mismatch can be stored as different amounts of Vh shifts in two CTTs that are connected to first and second data nodes.

The CTT-eNVSRAM can operate corresponding to SRAM during read and write modes, and can be integrated into a 22 nm FDSOI CMOS logic process.

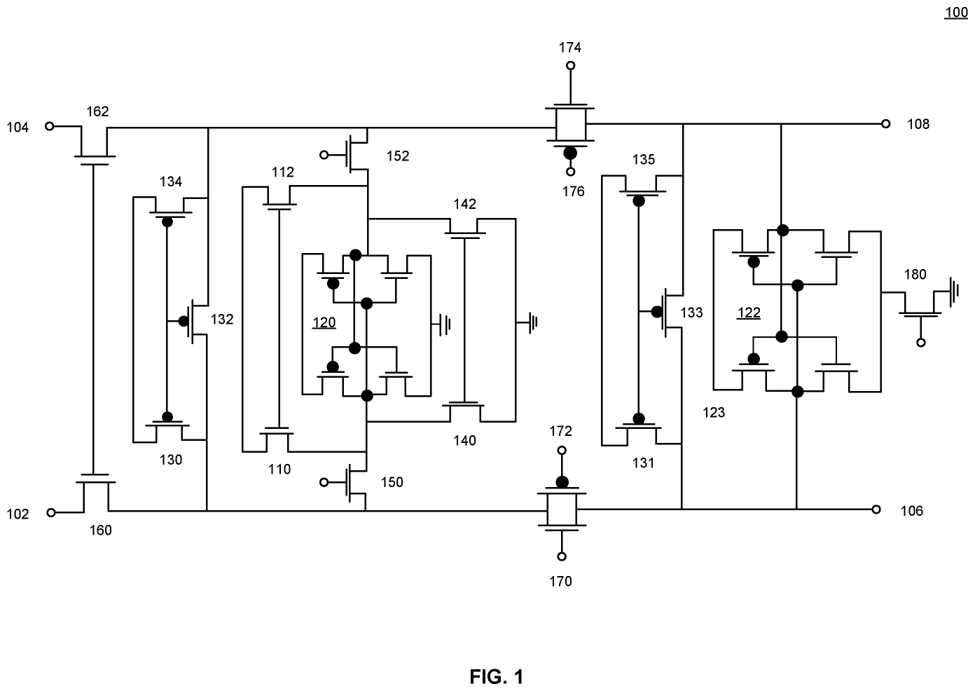

FIG. 1 illustrates a first electronic device in accordance with present implementations. As illustrated by way of example in FIG. 1, an example device 100 can include first and second write nodes 102 and 104, first and second sense nodes 106 and 108, first and second charge trap transistors 110 and 112, first and second memory arrays 120 and 122, bitcell power nodes 121 and 123, a first precharge transistor array including transistors 130, 132 and 134, a second precharge transistor array including transistors 131, 133 and 135, first and second assist gate transistors 140 and 142, first and second word line transistors 150 and 152, first and second write enable transistors 160 and 162, a first select transistor array including first and second select transistors 170 and 172, a second select transistor array including third and fourth select transistors 174 and 176, and a set transistor 180.

Present implementations can operate a memory device to generate strong and weak pull-ups at various data nodes. As one example, when a bitcell is on, a first data node can be 0.8 V and a second data node can be 0 V. To recover this state after power loss, a CTT operatively coupled with the first data node can be the stronger pull-up. To achieve this, the device can increase Vm of a CTT operatively coupled with the second data node by a programming operation. To program the CTTs 110 and 112, a VDD driving the CTTs 110 and 112 can be 1.3V, a gate voltage of the CTTs 110 and 112 can be 2.5V, a V_{GS} of the second CTT 112 can be greater than a V_{GS} of the first CTT 110, and a V_{DS} of the second CTT 112 can be greater than a V_{DS} of the first CTT 110. The device can program the second CTT 112 to a voltage higher than the first CTT 110, where the Vm of the second CTT 112 is greater than the Vm of the first CTT 110. Thus, the second CTT 112 can become a weaker pull-up during RECALL. Upon recall, the first data node can again be 0.8 V and the second data node can again be 0 V.

Present implementations also advantageously include first and second assist gate transistors 140 and 142 to assist with draining the CTT programming current. The first and second assist gate transistors 140 and 142 can include NFET transistors, to reduce voltage of a low side to 0V and high side to 0.8V and mitigate or eliminate excessive current spiking that can potentially destroy the ability of the memory device to restore a data state upon restoration of power. The device can erase the CTTs 110 and 112 after data recall to bring restore their respective Vm values to the original value, and to reuse them in the next programming cycle. An erase operation can include increasing VDD of the CTTs 110 and 112 to 0.8 V, and decreasing a gate voltage of the CTTs 110 and 112 to −1.2 V, to result in a bias V_{GS} of −2 V for the CTTs 110 and 112 to erase the data at each of the first and second data nodes.

The CTTs 110 and 112 can be programmed before the memory device transitions to an idle mode. As one example, a voltage level at a first data node can correspond to a logical 1, and a voltage level at a second data node can correspond to a logical 0. In the store mode, the second CTT 112 can be programmed to a higher voltage level than the first CTT 110, as a result of the V_{DS} of the second CTT 112 being greater than the V_{DS} of the first CTT 110. In the recall mode, when VDD for the CTTs 110 and 112 returns, a faster pull-up NFET on the first data node restores the logical 1 at the first data node.

A memory device can include a particular voltage application configuration corresponding to particular modes. In a read-write mode, VDD can be 0 V, gate voltages at the CTTs 110 and 112 can be 0 V, gate voltages at the first and second word line transistors 150 and 152 can be 0.8 V, and gate voltages at the first and second assist gate transistors 140 and 142 can be 0 V. In an idle mode, VDD can be 0 V, gate voltages at the CTTs 110 and 112 can be 0 V, gate voltages at the first and second word line transistors 150 and 152 can be 0.8 V, gate voltages at the first and second assist gate transistors 140 and 142 can be 0 V, and voltages at bit line input nodes can be 0.8 V. The bit line input nodes can respectively couple the first and second word line transistors 150 and 152 to the first and second write enable transistors 160 and 162. In a nonvolatile programming mode, VDD can be 0.8 V, gate voltages at the CTTs 110 and 112 can be 0.8 V, gate voltages at the first and second word line transistors 150 and 152 can be 0 V, and gate voltages at the first and second assist gate transistors 140 and 142 can be 0.8 V. In a nonvolatile recall mode, VDD can be 0.8 V, gate voltages at the CTTs 110 and 112 can be 0.8 V, gate voltages at the first and second word line transistors 150 and 152 can be 0 V, and gate voltages at the first and second assist gate transistors 140 and 142 can be 0 V. In a nonvolatile erase mode, VDD can be 0.8 V, gate voltages at the CTTs 110 and 112 can be −1.2 V, gate voltages at the first and second word line transistors 150 and 152 can be 0 V, and gate voltages at the first and second assist gate transistors 140 and 142 can be 0 V. As one example, programming can be performed two rows, or two pairs of CTTs, at a time to limit the total programming current. Recall and erase operations can be performed on the whole array at once.

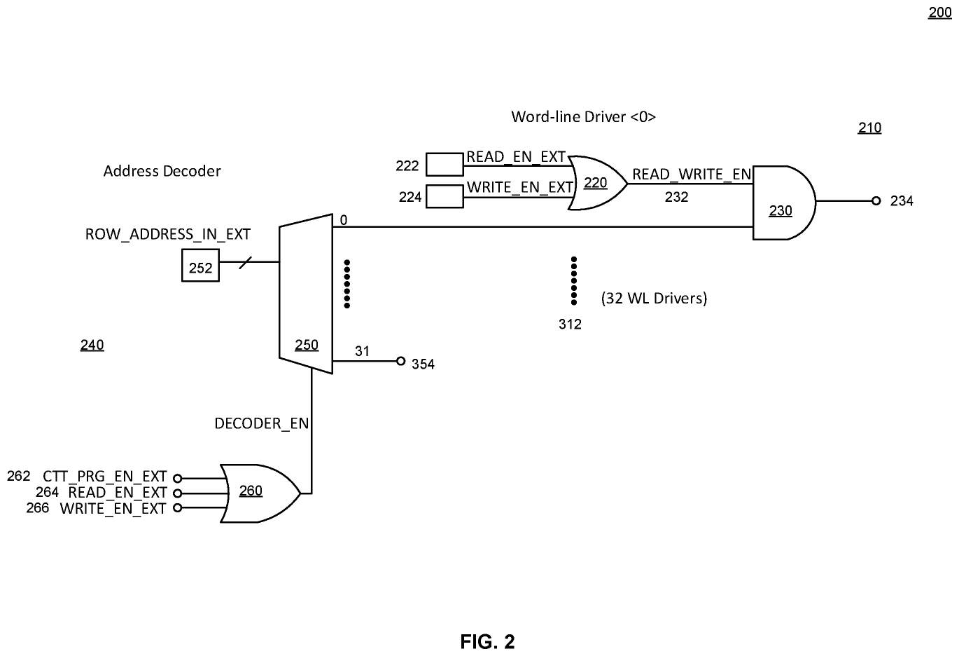

FIG. 2 illustrates a word line circuit in accordance with present implementations. As illustrated by way of example in FIG. 2, an example word line circuit 200 can include a word line driver circuit 210 and an address decoder circuit 240.

The word line driver circuit 210 can include an enable gate 220 and an output gate 230. The enable gate 220 can include an OR gate, can receive a read enable input at a read enable input node 222, can receive a write enable input at a write enable input node 224, and can generate a read-write enable signal at a read-write output node 232. The output gate 230 can receive the read-write enable signal at the read-write output node 232, can receive an address input from the address decoder 240, and can generate a write output signal at write driver output node 234. The output gate 230 can be operatively coupled with an output of the address decoder. It is to be understood that the word line circuit 200 can include a plurality of word line driver circuits 212 in accordance with word line driver circuit 210, with each of the word line driver circuits 212 operatively coupled with a respective output of the address decoder.

The address decoder circuit 240 can include a decoder 250 and a decoder enable gate 260. The decoder 250 can receive an address input from an address input channel 252, and can output an address input to one or more of the word line driver circuits 210 and 212 by one or more corresponding decoder output nodes 254. The address input channel 252 can include a plurality of bits. As one example, the address input channel 252 can be a 5-bit channel. The decoder enable gate 260 can include an OR gate, or can include a plurality of logic gates collectively comprising a multiple-input OR gate. The decoder enable gate 260 can receive a charge trap transistor program enable signal from program enable node 262, the read-write enable signal at a read-write node 264, and a write enable input at a write enable node 266.

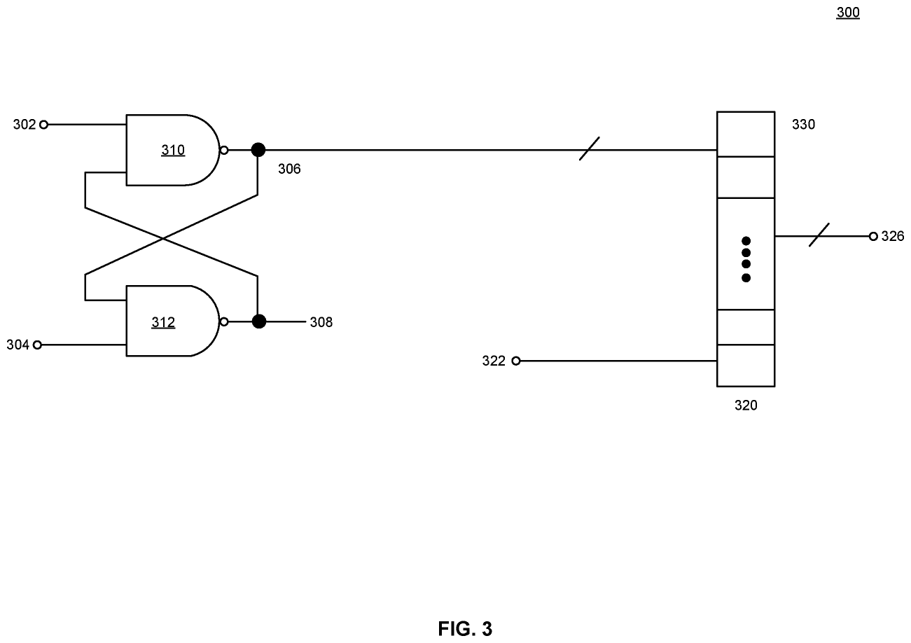

FIG. 3 illustrates a read circuit in accordance with present implementations. As illustrated by way of example in FIG. 3, an example read circuit 300 can include first and second sense nodes 302 and 304 and first and second data output nodes 306 and 308 of first and second output gates 310 and 312, an output shift register 320, a clock input node 322 to the output shift register 320, and a register output node 326. The output shift register 320 can include a plurality of register array locations 330.

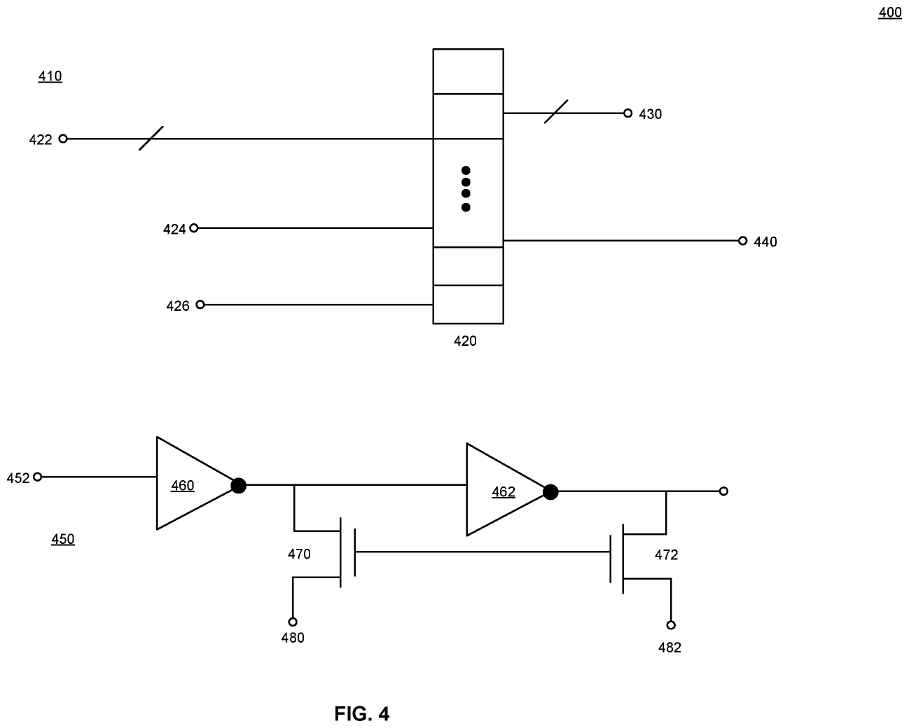

FIG. 4 illustrates a write circuit in accordance with present implementations. As illustrated by way of example in FIG. 4, an example write circuit 400 can include a write register circuit 410 and a write driver circuit 450. The write register circuit 410 can include an input shift register 420 that can receive a write input signal from a write input node 422, can receive a write enable signal from a write enable node 424, and can receive a clock input signal 426 from a clock input node 426. The input shift register 420 can generate a write output signal by a write output channel 430. The write output channel 430 can be a multi-bit channel. As one example, the write output channel 430 can be 32 bits. The input shift register 420 can also generate a write ready signal at a write ready node 440.

The write driver circuit 450 can include a write data input node 452 operatively coupled with an input of a first write gate 460. The write driver circuit 450 can be operatively coupled with the write register circuit 410, by the write output channel 430 being operatively coupled to the write data input node 452. Each bit of the write output channel 430 can be respectively coupled with a write data input node of a corresponding write driver circuit 450. Thus, the write driver circuit 450 can be one of a plurality of write driver circuits corresponding in number to the number of bits of the write output channel 430. As one example, the write circuit 400 can include 32 write driver circuits 450 where the write output channel 430 has 32 bits. The write output channel 430 can include a second write gate 460, a plurality of write enable transistors 470 and 472, and a plurality of bit line inputs nodes 480 and 482 operatively coupled respectively with the write enable transistors 470 and 472.

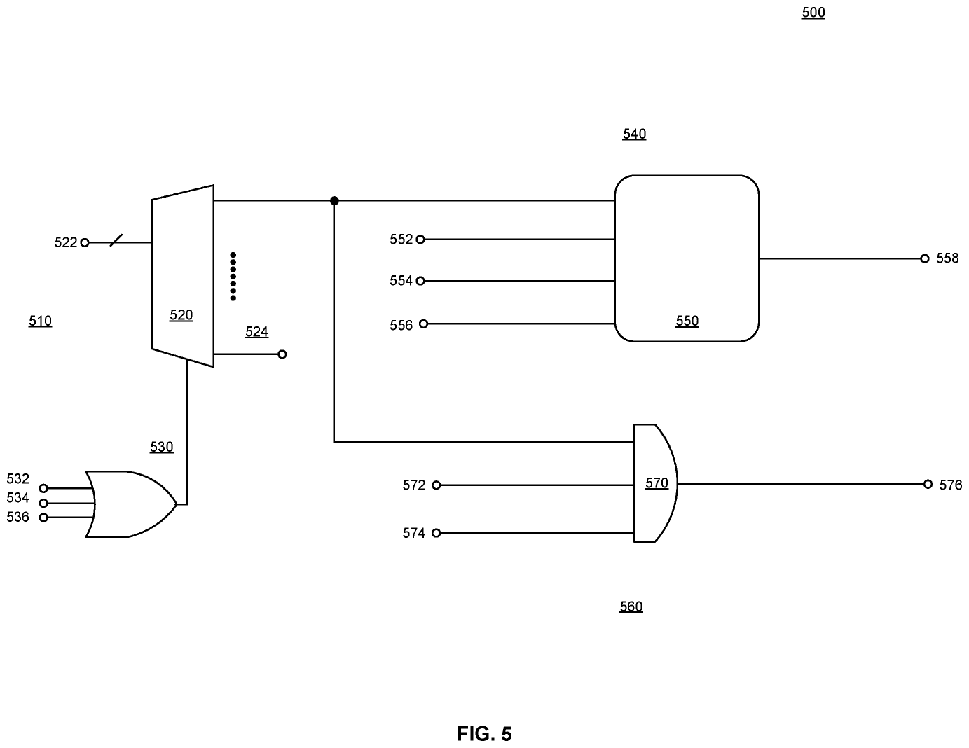

FIG. 5 illustrates a gate driver circuit in accordance with present implementations. As illustrated by way of example in FIG. 5, an example gate driver circuit 500 can include an address decoder circuit 510, a charge trap transistor gate driver circuit 540, and an assist gate driver circuit 560.

The address decoder circuit 510 can include a decoder 520 and a decoder enable gate 530. The decoder 520 can receive an address input from an address input channel 522, and can output an address input to one or more of the charge trap transistor gate driver circuit 540 and the assist gate driver circuit 570, by one or more corresponding decoder output nodes 524. The address input channel 522 can include a plurality of bits. As one example, the address input channel 522 can be a 5-bit channel. The decoder enable gate 530 can include an OR gate, or can include a plurality of logic gates collectively comprising a multiple-input OR gate. The decoder enable gate 530 can receive the charge trap transistor program enable signal from program enable node 532, the read-write enable signal at a read-write node 534, and the write enable input at a write enable node 536.

The charge trap transistor gate driver circuit 540 can include a level shifter circuit that can receive the charge trap transistor program enable signal from program enable node 552, a recall signal from recall node 554, and second enable signal from a second enable node 556. The charge trap transistor gate driver circuit 540 can activate and deactivate one or more charge trap transistors by a driver output signal generated at the output node 558. The output node 558 can be coupled to gate terminals of one or more charge trap transistors.

The assist gate driver circuit 560 can include a driver gate 570. The driver gate 570 can include an AND gate, or can include a plurality of logic gates collectively comprising a multiple-input AND gate. The assist gate driver circuit 570 can receive the charge trap transistor program enable signal from program enable node 572, and can receive an assist transistor program enable signal from assist enable node 574. The assist gate driver circuit 570 can activate and deactivate one or more assist transistors by a driver output signal generated at output node 576. The output node 558 can be coupled to gate terminals of one or more assist transistors. As one example, assist transistors can be NFET transistors.

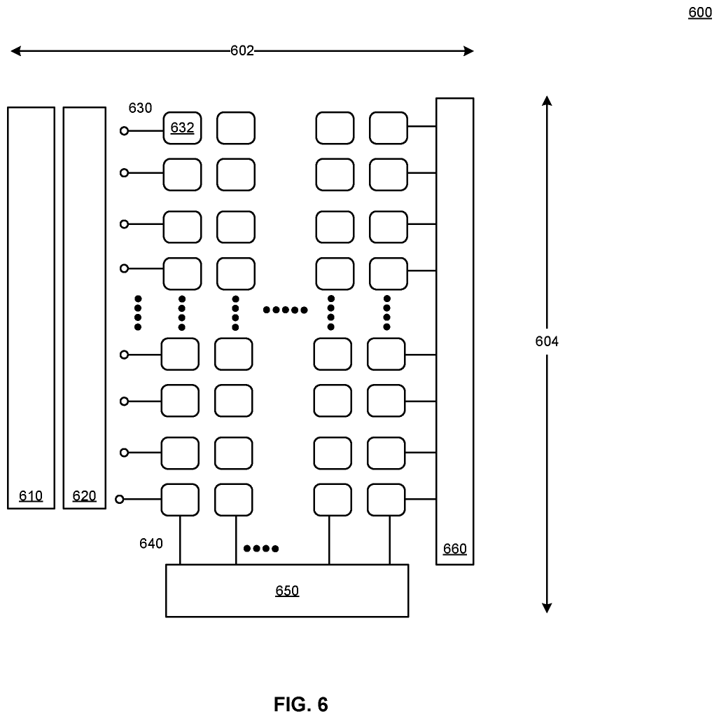

FIG. 6 illustrates an interface array in accordance with present implementations. As illustrated by way of example in FIG. 6, an example interface array 600 can be an integrated circuit device including a level shifter region 610, a write driver region 620, a bit line channel region 630 and a word line channel region 640, a digital control unit region 650, and a management circuit region 660. The level shifter region 610 can include fabricated therein one or more level shifters operatively coupled to the one or more charge trap transistors. The level shifters can include one or more shift registers 320, 420 and 550, for example. The write driver region 620 can include fabricated therein one or more write drivers 450. The bit line channel region 630 and the word line channel region 640 can be operatively coupled to circuits of the regions 620, 650 and 660, and can be operatively coupled to various node terminal pads 632. The interface array 600 can be fabricated to have a particular width 602 and length 604 in accordance with a planar surface of a fabricated semiconductor device. As one example, the width 602 can be 30 um and the height 604 can be 132 um.

An example memory device can have a package size of 1×2 mm² and can include a 1 Kb CTT-eNVSRAM array with peripheries. The device can include 22 digital IO pads of 17 input pads and 5 output pads. The device can include 13 power pads of 2 digital and 11 analog power pads. Digital power pads can include VDDIO and VDD!. Analog power pads can include VDDIO_HIGH, 3 VDD_BITCELL, 3 CTT_VDD, CTT_SUP_PRG, CTT_SUP_ERS, VDD_SA, and NWELL_BIAS. The device can include 6 ground (GND) pads.

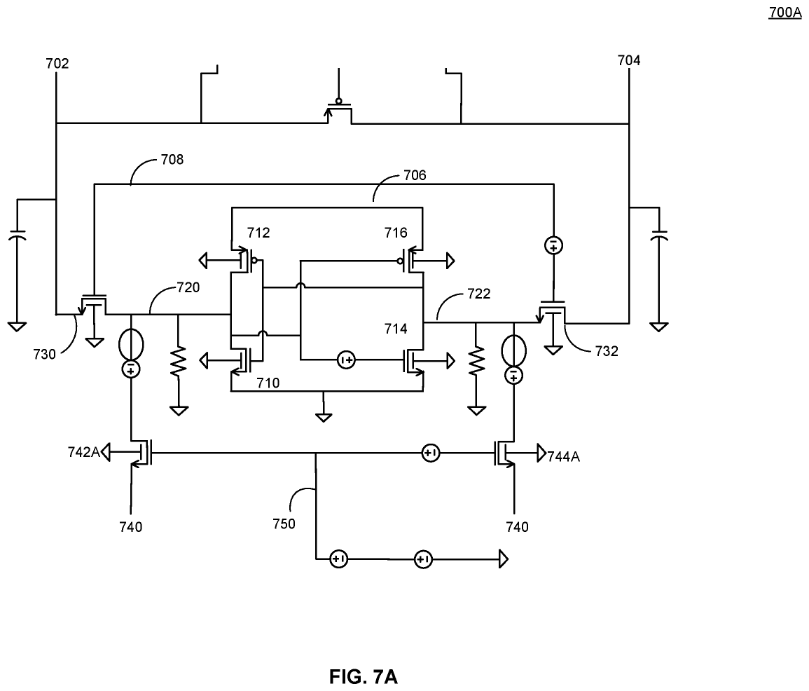

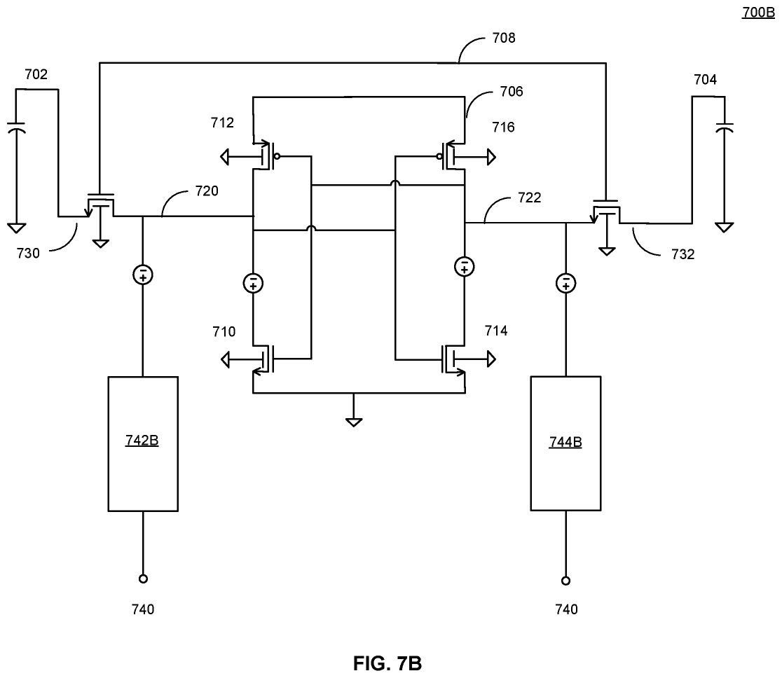

FIG. 7A illustrates a second electronic device in accordance with present implementations. As illustrated by way of example in FIG. 7A, an example electronic device 700A can include a transistor array including transistors 710, 712, 714, and 716, first and second data nodes 720 and 722, first and second word line transistors 730 and 732, and first and second assist transistors 742A and 744A. The electronic device 700A can receive first and second bit line inputs 702 and 704, a VDD voltage 706, a word line input 708, a nonvolatile VDD voltage 740, and a nonvolatile gate voltage 750 that can receive a recall input signal. The transistors 710, 712, 714, and 716 can be charge trap transistors. The first and second assist transistors 742A and 742A can be NFET transistors, for example.

FIG. 7B illustrates a third electronic device in accordance with present implementations. As illustrated by way of example in FIG. 7B, an example electronic device 700B can include the transistor array including the transistors 710, 712, 714, and 716, the first and second data nodes 720 and 722, the first and second word line transistors 730 and 732, and the first and second assist circuits 742B and 744B. The electronic device 700A can receive the first and second bit line inputs 702 and 704, the VDD voltage 706, the word line input 708, and the nonvolatile VDD voltage 740. The transistors 710, 712, 714, and 716 can be charge trap transistors. The first and second assist circuits 742B and 744B can include, within a separate fabricated device, transistors and circuitry to implement the nonvolatile gate voltage input, for example.

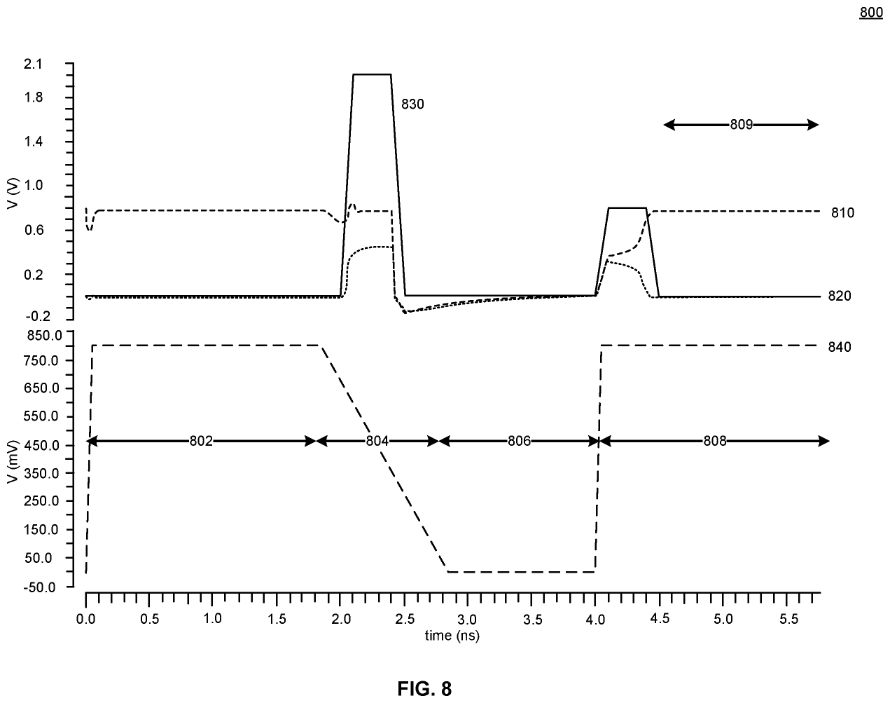

FIG. 8 illustrates a first voltage diagram in accordance with present implementations. As illustrated by way of example in FIG. 8, an example voltage diagram 800 can include voltage waveforms 810, 820, 830 and 840 over periods 802, 804, 806, 808 and 809. Data voltage 810 corresponds to a voltage at a first data node. Data voltage 820 corresponds to a voltage at a second data node. The nonvolatile voltage 830 corresponds to a voltage of a recall gate signal. The recall gate signal can correspond, for example, to the nonvolatile gate voltage 750. Cell voltage 840 corresponds to a voltage at a VDD node of a charge trap transistor array. The cell voltage 840 can correspond to voltage at bitcell power nodes 121 or 123, for example.

During period 802, the data voltage 810 holds a logical high or ‘1’ data state, the data voltage 820 holds a logical low or ‘0’ data state, the nonvolatile voltage 830 maintains a low state indicating stable power from the cell voltage 840, and the cell voltage is high, providing sufficient power to maintain the states of the data voltages 810 and 820. During period 804, the data voltage 810 begins to lose the logical high or ‘1’ data state by dropping, the data voltage 820 begins to lose the logical low or ‘0’ data state by spiking, the nonvolatile voltage 830 transitions to a high state indicating dropping power from the cell voltage 840, and the cell voltage 840 drops to low, no longer providing sufficient power to maintain the states of the data voltages 810 and 820.

During period 806, the data voltage 810 has the logical low or ‘0’ data state, the data voltage 820 returns to the logical low or ‘0’ data state, the nonvolatile voltage 830 transitions to the low state, and the cell voltage 840 maintains an electrical low level, no longer providing power to the memory device including the data voltages 810 and 820. During period 808, the data voltage 810 begins to regain the logical high or ‘1’ data state by increasing, the data voltage 820 begins to regain the logical low or ‘0’ data state by spiking, the nonvolatile voltage 830 transitions to another high state indicating increasing power from the cell voltage 840, and the cell voltage 840 rises to high, again providing sufficient power to return the data voltages 810 and 820 to their prior states before power loss. During period 809, the data voltage 810 again holds a logical high or ‘1’ data state, the data voltage 820 again holds a logical low or ‘0’ data state, the nonvolatile voltage 830 again maintains a low state indicating stable power from the cell voltage 840, and the cell voltage is again high, providing sufficient power to maintain the states of the data voltages 810 and 820.

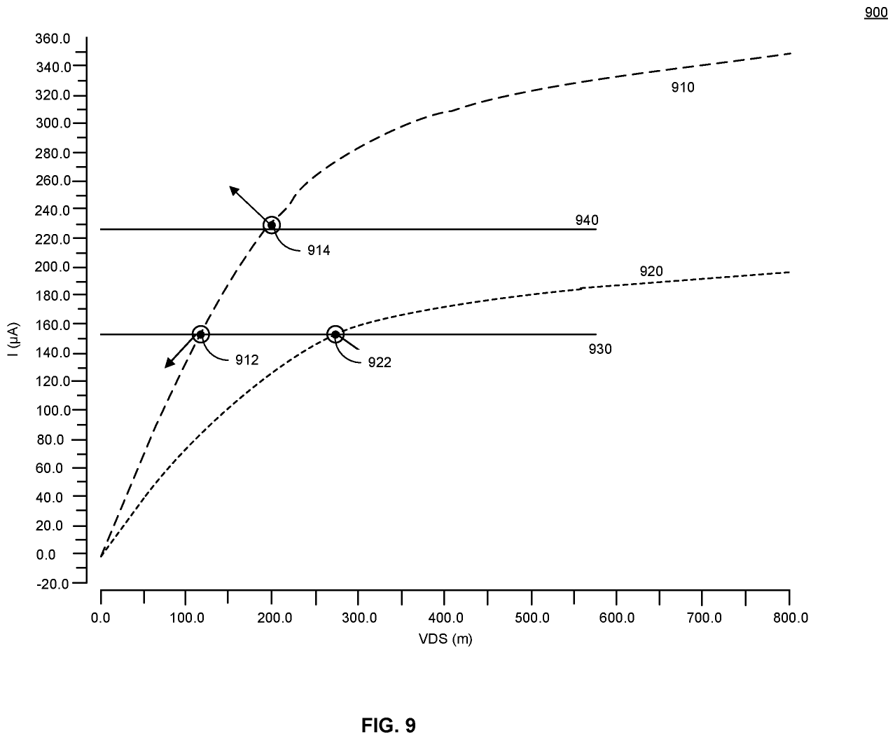

FIG. 9 illustrates a second voltage diagram in accordance with present implementations. As illustrated by way of example in FIG. 9, an example voltage diagram 900 can include voltage waveforms 910 and 920 and voltage threshold 930 and 940. The first voltage threshold 930 can correspond to a programming voltage for an NFET transistor having a first physical profile. As one example, a first physical profile can include a transistor scale of 120 nm and bias voltage of 230 uA. The second voltage threshold 940 can correspond to a programming voltage for an NFET transistor having a second physical profile. As one example, a second physical profile can include a transistor scale of 80 nm and bias voltage of 153 uA. The first voltage waveform 910 can include programming voltages 912 and 914, associated with the threshold 940 and 930, respectively. As one example, the programming voltage 912 can be approximately 117 mV, and the programming voltage 914 can be approximately 198 mV. The second voltage waveform 920 can include programming voltage 922, associated with the threshold 930. As one example, the programming voltage 922 can be approximately 274 mV. The programming voltages can correspond to V_{DS} voltages for the NFET transistor to enable operation in accordance with FIG. 8.

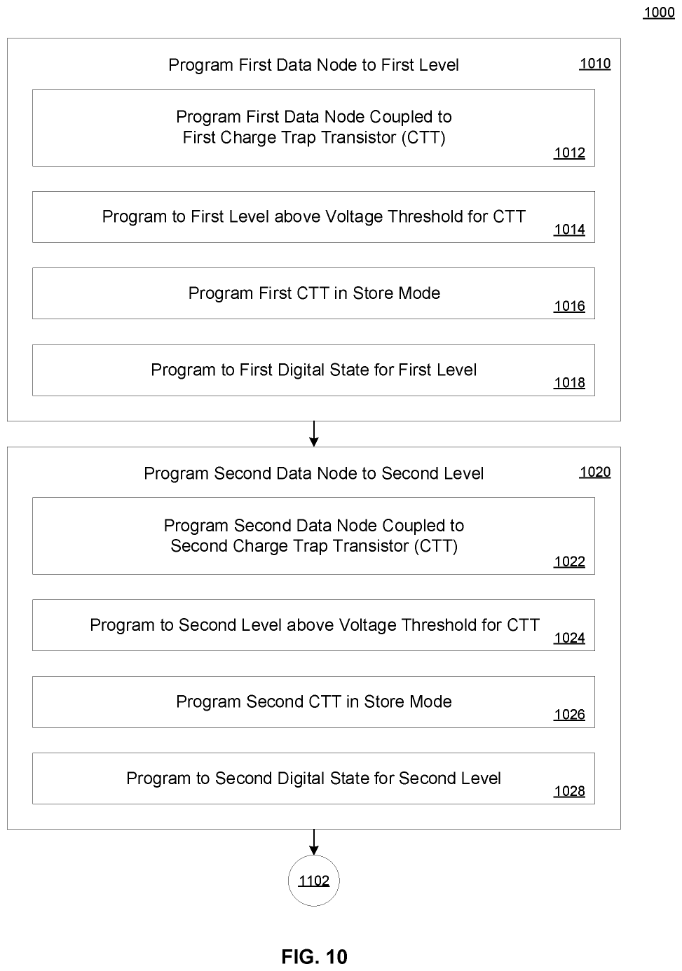

FIG. 10 illustrates a first method of operating a nonvolatile memory device with charge trap transistor structures, in accordance with present implementations. At least one of the devices 100, 200, 300, 400, 500, 600, 700A and 700B can perform method 1000 according to present implementations. The method 1000 can begin at step 1010.

At step 1010, the method can program a first data node to a first level. The first level can correspond to a first voltage level. Step 1010 can include at least one of steps 1012, 1014, 1016 and 1018. At step 1012, the method can program a first data node coupled to a first charge trap transistor. At step 1014, the method can program a first charge trap transistor to a first level over a voltage threshold associated with the charge trap transistor. At step 1016, the method can program the first charge trap transistor in a store mode. At step 1018, the method can program a first charge trap transistor to a first digital state corresponding to the first voltage level. The method 1000 can then continue to step 1020.

At step 1020, the method can program a second data node to a second level. The second level can correspond to a second voltage level. Step 1020 can include at least one of steps 1022, 1024, 1026 and 1028. At step 1022, the method can program a second data node coupled to a second charge trap transistor. At step 1024, the method can program a second charge trap transistor to a second level over a voltage threshold associated with the charge trap transistor. At step 1026, the method can program the second charge trap transistor in a store mode. At step 1028, the method can program a second charge trap transistor to a second digital state corresponding to the second voltage level. The method 1000 can then continue to step 1102.

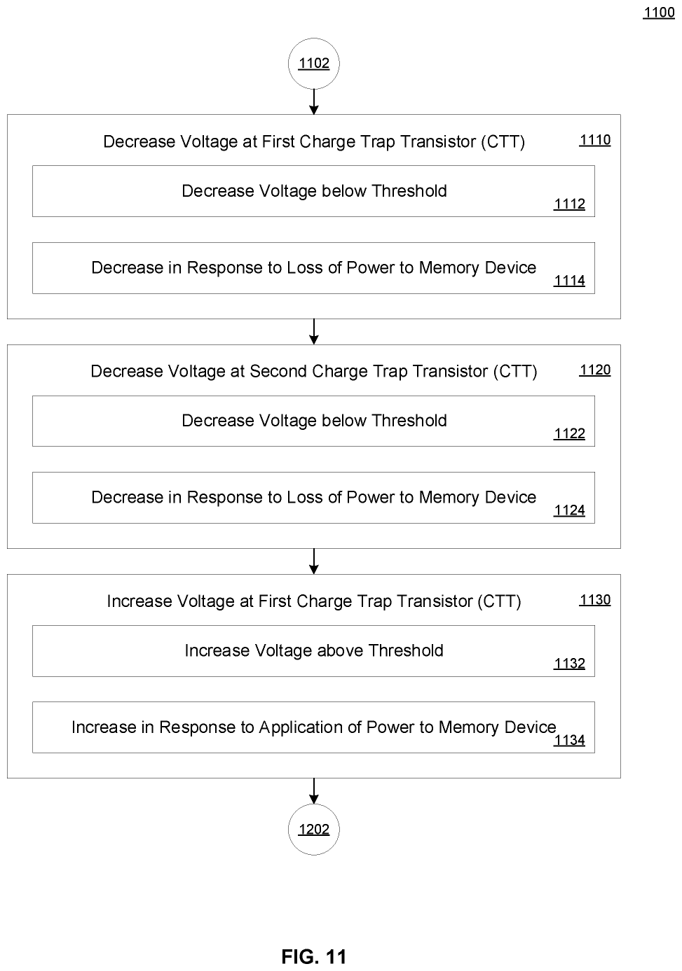

FIG. 11 illustrates a second method of operating a nonvolatile memory device with charge trap transistor structures, further to the method of FIG. 10. At least one of the devices 100, 200, 300, 400, 500, 600, 700A and 700B can perform method 1100 according to present implementations. The method 1100 can begin at step 1102. The method 1100 can then continue to step 1110.

At step 1110, the method can decrease a first voltage at a first charge trap transistor. Step 1110 can include at least one of steps 1112 and 1114. At step 1112, the method can decrease the first voltage below a threshold. This threshold can correspond to a common threshold or a particular threshold associated with the first charge trap transistor. At step 1114, the method can decrease the voltage in response to loss of power to a memory device including the first charge trap transistor. A power loss can include a complete or partial loss of power, or a reduction in available power to inhibit normal operation of the memory device. The method 1100 can then continue to step 1120.

At step 1120, the method can decrease a second voltage at a second charge trap transistor. Step 1120 can include at least one of steps 1122 and 1124. At step 1122, the method can decrease the first voltage below a threshold. This threshold can correspond to a common threshold or a particular threshold associated with the second charge trap transistor. At step 1124, the method can decrease the voltage in response to loss of power to a memory device including the first charge trap transistor. The method 1100 can then continue to step 1130.

At step 1130, the method can increase a first voltage at a first charge trap transistor. Step 1130 can include at least one of steps 1132 and 1134. At step 1132, the method can increase the first voltage to or above a threshold. At step 1134, the method can increase the voltage in response to an application of power to a memory device including the first charge trap transistor. The application of power can include a restoration of power to the memory after a power loss. The method 1100 can then continue to step 1202.

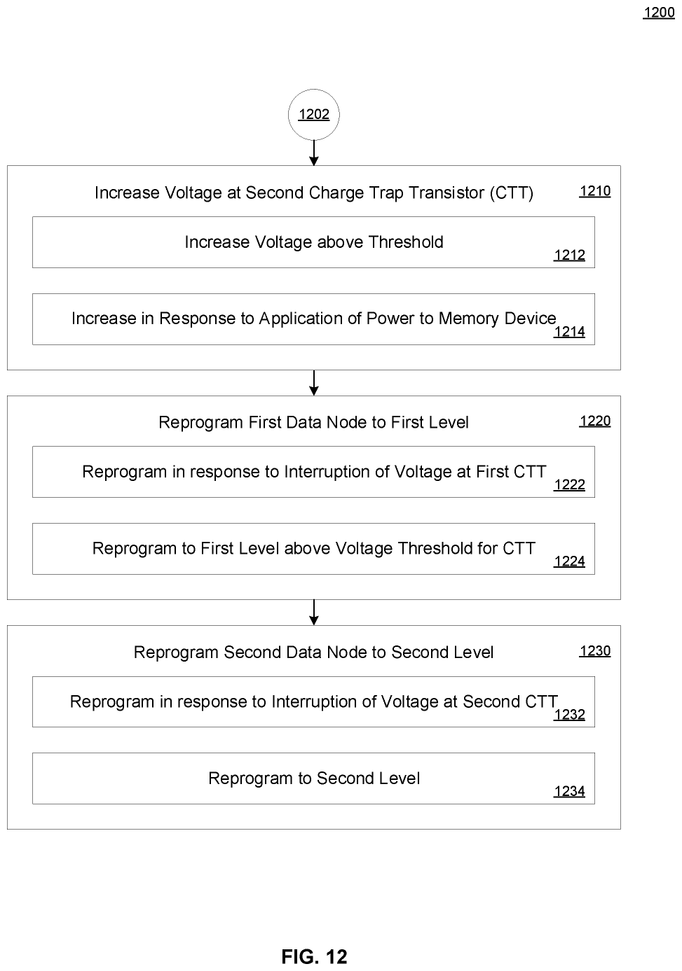

FIG. 12 illustrates a third method of operating a nonvolatile memory device with charge trap transistor structures, further to the method of FIG. 11. At least one of the devices 100, 200, 300, 400, 500, 600, 700A and 700B can perform method 1200 according to present implementations. The method 1200 can begin at step 1202. The method 1200 can then continue to step 1210.

At step 1210, the method can increase a second voltage at a first charge trap transistor. Step 1210 can include at least one of steps 1212 and 1214. At step 1212, the method can increase the first voltage to or above a threshold. At step 1214, the method can increase the voltage in response to an application of power to a memory device including the first charge trap transistor. The method 1200 can then continue to step 1220.

At step 1220, the method can reprogram a first data node to a first level. Step 1220 can include at least one of steps 1222 and 1224. At step 1222, the method can reprogram the first data node in response to an interruption of a voltage applied at a first charge trap transistor. At step 1224, the method can reprogram the first charge trap transistor to a first level of a voltage threshold associated with the first charge trap transistor. The reprogramming can thus restore a binary value associated with or binary state of the first charge trap transistor in response to low of power. The method 1200 can then continue to step 1230.

At step 1230, the method can reprogram a second data node to a second level. Step 1230 can include at least one of steps 1232 and 1234. At step 1232, the method can reprogram the second data node in response to an interruption of a voltage applied at a second charge trap transistor. At step 1234, the method can reprogram the second charge trap transistor to a second level of a voltage threshold associated with the second charge trap transistor. The reprogramming can thus restore a binary value associated with or binary state of the second ‘charge trap transistor in response to low of power. The method 1200 can end at step 1230.

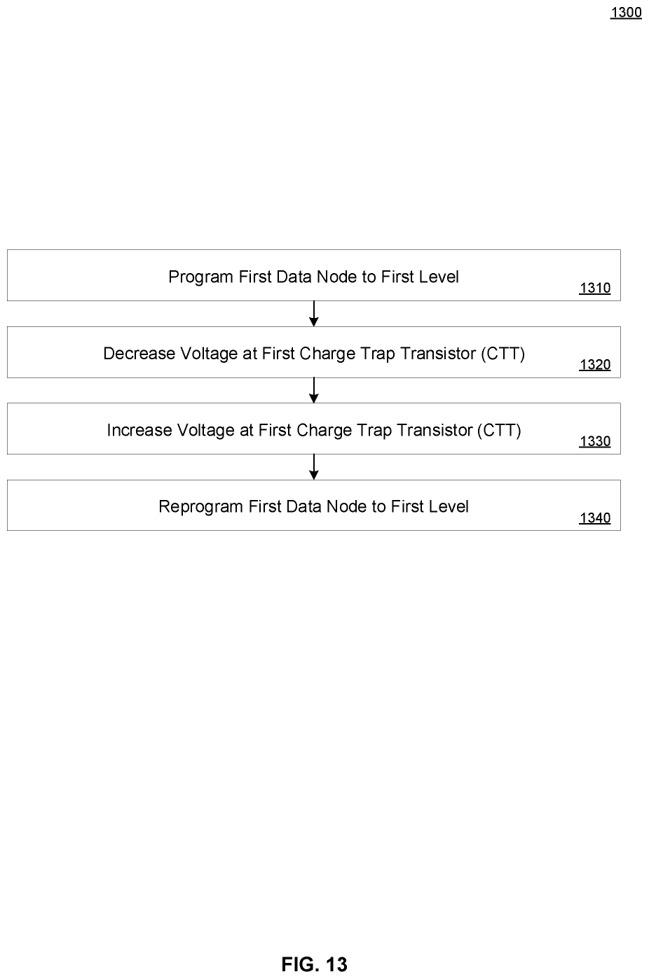

FIG. 13 illustrates a fourth method of operating a nonvolatile memory device with charge trap transistor structures, in accordance with present implementations. At least one of the devices 100, 200, 300, 400, 500, 600, 700A and 700B can perform method 1300 according to present implementations. The method 1300 can begin at step 1310.

At step 1310, the method can program a first data node to a first level. The method 1300 can then continue to step 1320. At step 1320, the method can decrease a first voltage at a first charge trap transistor. The method 1300 can then continue to step 1330. At step 1330, the method can increase a first voltage at a first charge trap transistor. The method 100 can then continue to step 1340. At step 1340, the method can reprogram a first data node to a first level. The method 1300 can end at step 1340. As discussed herein with respect to methods 1000-1200, programming a data node can correspond to directly or indirectly applying a particular electrical signal to a data node, and programming a charge trap transistor can correspond to directly or indirectly a particular electrical signal to one or more terminals of a charge trap transistor. Programming one or the other of the charge trap transistor and a data node with which it is operatively coupled, can result in programming of the corresponding data node or charge trap transistor.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include, but are not limited to, physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

The foregoing description of illustrative implementations has been presented for purposes of illustration and of description. It is not intended to be exhaustive or limiting with respect to the precise form disclosed, and modifications and variations are possible in light of the above teachings or may be acquired from practice of the disclosed implementations. It is intended that the scope of the invention be defined by the claims appended hereto and their equivalents.

1. A method of memory storage, comprising:
programming a first data node operatively coupled to a first charge trap transistor to a first level above a threshold;
decreasing, below the threshold, a first voltage at the first charge trap transistor;
increasing, above the threshold, the first voltage at the first charge trap transistor; and
reprogramming, the first data node to the first level, in response to an interruption of the first voltage at the first charge trap transistor caused by the decreasing and the increasing.

2. The method of claim 1, further comprising:
programming the first charge trap transistor at the first level in a store mode.

3. The method of claim 1, wherein the first level corresponds to a first digital state.

4. The method of claim 1, wherein the programming the first data node comprises setting the first node voltage at the first data node to the first level based on a first transistor voltage across a drain and a source of the first charge trap transistor.

5. The method of claim 1, further comprising:
programming a second data node operatively coupled to a second charge trap transistor to a second level.

6. The method of claim 5, further comprising:
reprogramming, the second data node to the second level, in response to an interruption of the second voltage at the second charge trap transistor caused by the decreasing and the increasing.

7. The method of claim 5, further comprising:
programming the second charge trap transistor at the second level in a store mode.

8. The method of claim 5, wherein the second level corresponds to a second digital state.

9. The method of claim 7, wherein the programming the second data node comprises setting the second node voltage at the second data node to the second level based on a second voltage across a drain and a source of the second charge trap transistor.

10. A memory device, comprising:
a first charge trap transistor;
a second charge trap transistor; and
a memory operatively coupled to the first charge trap transistor and the second charge trap transistor.

11. The device of claim 10, wherein the first charge trap transistor and the second charge trap transistor are operatively coupled to an input voltage node.

12. The device of claim 10, wherein the memory comprises a nonvolatile static ram bitcell.

13. The device of claim 10, further comprising:
a first input transistor operatively coupled with the first charge trap transistor; and
a second input transistor operatively coupled with the second charge trap transistor.

14. The device of claim 13, wherein the first input transistor is operatively coupled with a first input node.

15. The device of claim 14, wherein the first input node comprises a first bit line input node.

16. The device of claim 13, wherein the second input transistor is operatively coupled with a second input node.

17. The device of claim 16, wherein the second input node comprises a second bit line input node.

18. The device of claim 13, wherein the first input transistor is operatively coupled with a third input node.

19. The device of claim 18, wherein the third input node comprises a first word line input node.

20. The device of claim 19, further comprising:
a first word line driver operatively coupled to the first word line input, the first word line driver comprising at least one logical gate and operatively coupled with an address decoder.

21. The device of claim 13, wherein the second input transistor is operatively coupled with a fourth input node.

22. The device of claim 21, wherein the fourth input node comprises a second word line input node.

23. The device of claim 22, further comprising:
a second word line driver operatively coupled to the second word line input node, the second word line driver comprising at least one logical gate and operatively coupled with an address decoder.

24. The device of claim 10, further comprising:
a first selector device operatively coupled with the first charge trap transistor and a first output node; and
a second selector device operatively coupled with the second charge trap transistor and a second output node.

25. The device of claim 24, further comprising:
a read device operatively coupled with the first output node and the second output node, the read device comprising a logical circuit.

26. The device of claim 25, wherein the logical circuit comprises an SR flip-flop.

27. A memory device comprising:
a plurality of level shifter devices operatively responsive to a plurality of charge trap transistor devices;
a write driver device operatively coupled with a plurality of bit line input nodes;
a controller operatively coupled with a plurality of word line input nodes.

28. The device of claim 27, wherein each of the charge trap transistor devices is operable to:
program, to a first level above a threshold, a plurality of data nodes operatively coupled to corresponding ones of the charge trap transistors;
decrease, below the threshold, a plurality of voltages at the charge trap transistors;
increase, above the threshold, the voltages at the charge trap transistors; and
reprogram, in response to an interruption of the voltages at the charge trap transistors, the data nodes to the first level.

29. The device of claim 28, wherein the interruption is caused by the decrease and the increase.
